(19) United States
(12) Patent Application Publication
(10) Pub. No.: US 2002/0048159 A1
(43) Pub. Date: Apr. 25, 2002

(54) Surface-mountable impedance device

(76) Inventors: Wei-Chun Tsao, Chung-Ho City (TW); Po-Yi Chen, Chung-Ho City (TW)

Correspondence Address: HARNESS, DICKEY & PIERCE, P. L. C., 5445 Corporate Drive, Troy, MI, 48098, US

(21) Appl. No.: 09/725,830

(22) Filed: Nov. 29, 2000

(30) Foreign Application Priority Data
Oct. 24, 2000 (TW) 089218466

(51) Int. Cl. H05K 7/02; H05K 7/04

(52) U.S. Cl. 361/807

(57) ABSTRACT

A surface-mountable impedance device includes a substrate formed as a non-ceramic circuit board, and an iron core. The substrate has a contact mounting side adapted to be mounted on a main board of an electronic device, and a core mounting side opposite to the contact mounting side. The substrate is formed with a plurality of mounting holes that extend from the contact mounting side and through the core mounting side. The iron core is mounted on the core mounting side of the substrate, and has opposite end surfaces that are transverse to the substrate and that are formed with a pair of strand holes therethrough. Each of plurality of coil strands passes through a respective one of the strand holes, is wound around the iron core, and has opposite first and second end portions that extend to the contact mounting side of the substrate via the mounting holes, respectively. A plurality of solder contacts are formed on the contact mounting side of the substrate to retain the first and second end portions of the coil strands on the substrate at the mounting holes, respectively. The solder contacts are adapted to connect electrically with the main board.

### BACKGROUND OF THE INVENTION

1. Field of the Invention

The invention relates to a surface-mountable impedance device, more particularly to a surface-mountable impedance device having a substrate formed as a non-ceramic circuit board.

2. Description of the Related Art

FIG. 1 illustrates a conventional surface-mountable impedance device. The conventional impedance device includes a substrate 11, which is made of a ceramic material, an iron core 13 mounted on the substrate 11, and a plurality of coil strands 14. The substrate 11 is formed with a plurality of contact pads 111, each of which has a through hole 112 formed therein by means of a specific laser-type punch to prevent breaking of the substrate 11. The iron core 13 has opposite end surfaces formed with a pair of strand holes 15 therethrough. Each of coil strands 14 passes through a respective one of the strand holes 15 and is wound around the iron core 13 so as to form a plurality of end portions 16 that extend through the substrate 11 via the through holes 112, respectively. Each of the end portions 16 is soldered in a respective one of the through holes 112 by means of a solder machine. It is noted that the laser-type punch and the solder machine are required to manufacture the conventional impedance device, and that it is necessary to prepare different molds when fabricating different sizes of the substrate 11, thereby resulting in an increased production cost.

FIG. 2 illustrates another conventional surface-mountable impedance device. Unlike the aforesaid conventional impedance device of FIG. 1, the substrate 21 is made of bakelite. The iron core 23 is mounted on a mounting plate 27 that is disposed on the substrate 21. The end portions 26 of the coil strands 24 are wound and soldered to a plurality of supporting feet 271 that extend outwardly and downwardly from opposite ends of the mounting plate 27 to the substrate 21, respectively. Due to the small size of the impedance device, and because winding and soldering the end portions 26 of the supporting feet 271 are done manually, an increase in production time is incurred. Furthermore, since bakelite has a poor high frequency impedance characteristic, the signal transmission efficiency of the conventional impedance device of FIG. 2 is accordingly reduced.

### SUMMARY OF THE INVENTION

Therefore, the main object of the present invention is to provide a surface-mountable impedance device that can be produced at a relatively low cost and using a relatively simple process.

According to the present invention, a surface-mountable impedance device includes a substrate, an iron core, a plurality of coil strands and a plurality of conductive solder contacts.

The substrate, which is formed as a non-ceramic circuit board, has a contact mounting side adapted to be mounted on a main board of an electronic device, and a core mounting side opposite to the contact mounting side. The substrate is formed with a plurality of mounting holes that extend from the contact mounting side and through the core mounting side.

The iron core is mounted on the core mounting side of the substrate. The iron core has opposite end surfaces that are transverse to the substrate and that are formed with a pair of strand holes therethrough.

Each of the coil strands passes through a respective one of the strand holes, and is wound around the iron core. The coil strands have opposite first and second end portions that extend to the contact mounting side of the substrate via the mounting holes, respectively.

The solder contacts are formed on the contact mounting side of the substrate to retain the first and second end portions of the coil strands on the substrate at the mounting holes, respectively. The solder contacts are adapted to connect electrically with the main board.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of a conventional surface-mountable impedance device;

FIG. 2 is a perspective view of another conventional surface-mountable impedance device;

FIG. 3 is an exploded perspective view of the preferred embodiment of a surface-mountable impedance device according to this invention;

FIG. 4 is perspective view showing a plurality of coil strands wound around an iron core of the preferred embodiment;

FIG. 5 is a perspective view of the preferred embodiment; and

FIG. 6 is a schematic side view showing how the preferred embodiment is mounted on a main board of an electronic device.

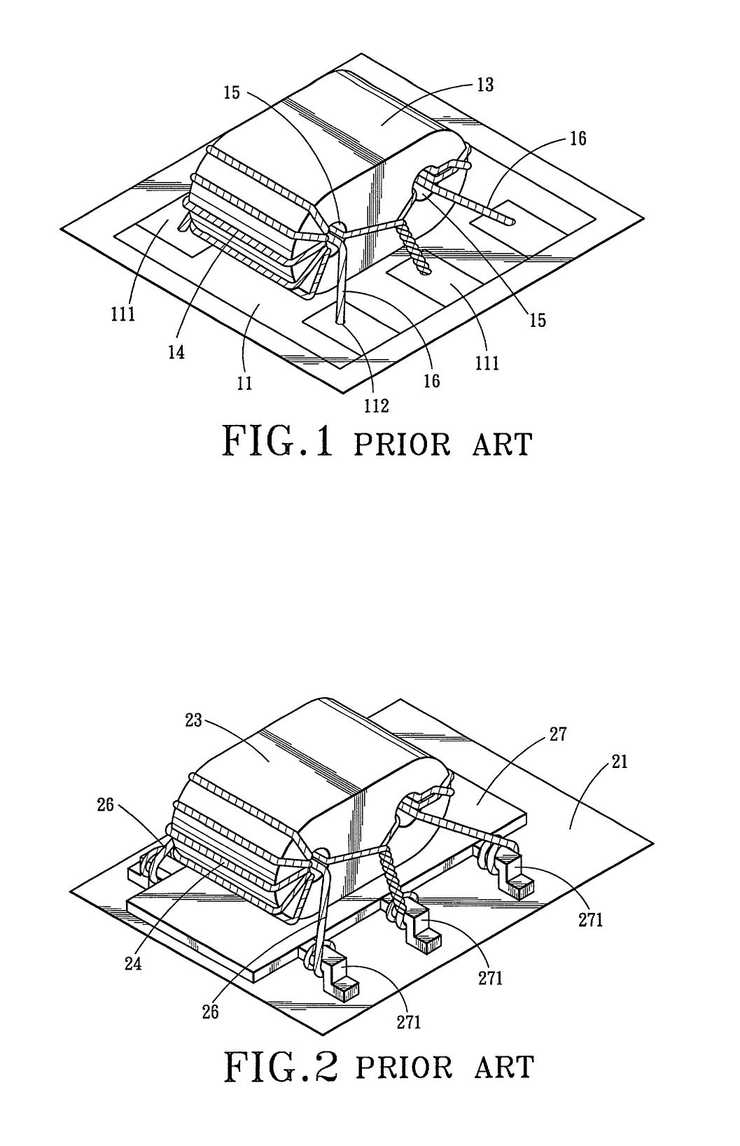

### DETAILED DESCRIPTION OF THE PREFERRED EMBODIMENT

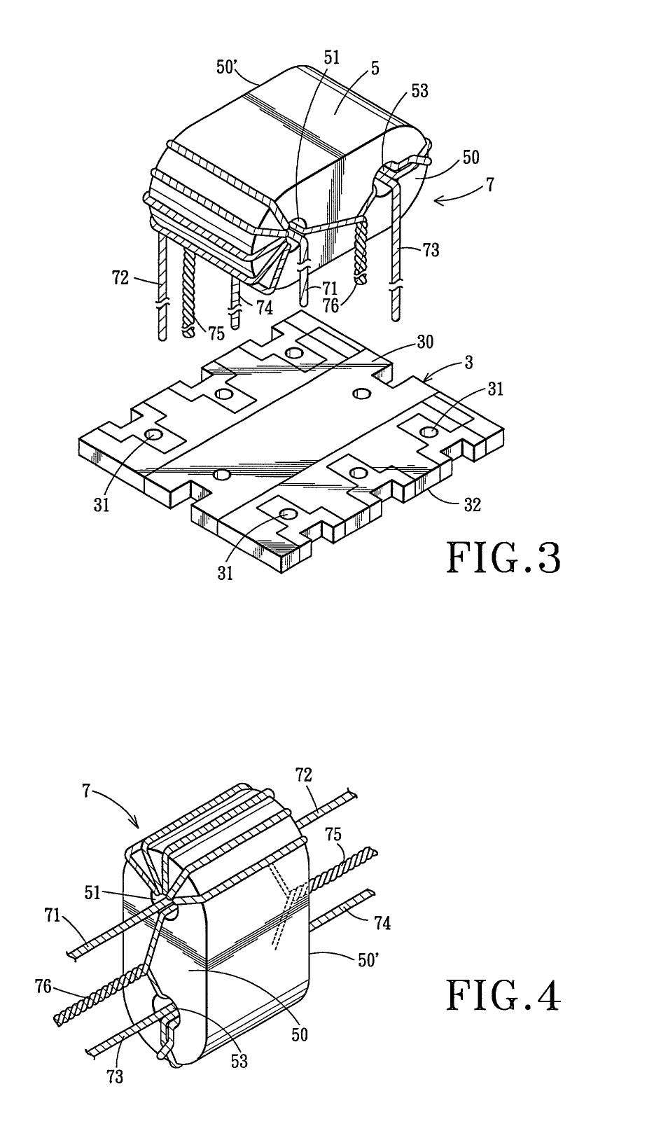

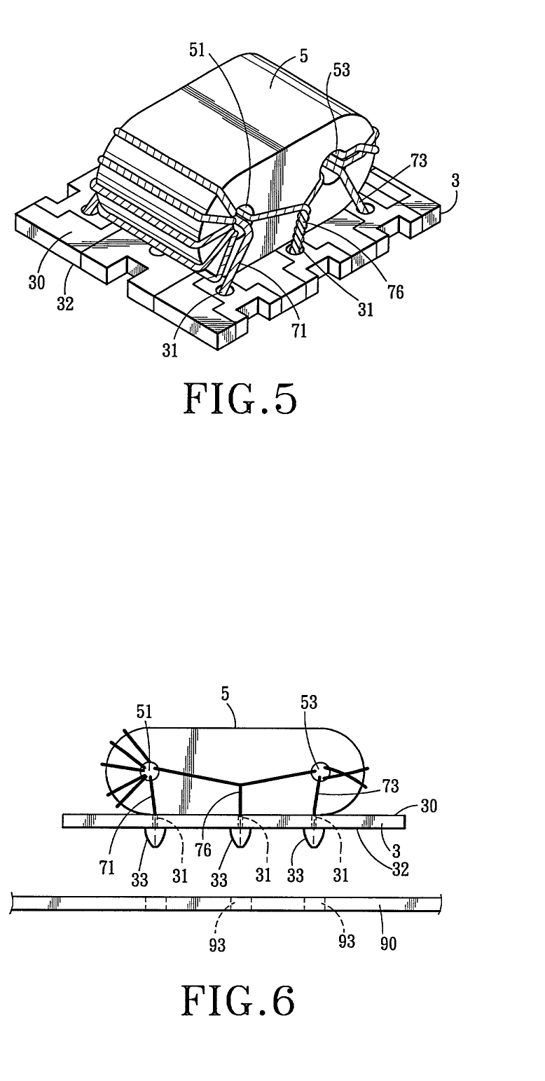

Referring to FIGS. 3, 5 and 6, according to the preferred embodiment of this invention, a surface-mountable impedance device is shown to include a substrate 3, an iron core 5, a plurality of coil strands 7, and a plurality of conductive solder contacts 33.

The substrate 3, which is formed as a non-ceramic circuit board that is generally rectangular, has a contact mounting side 32 adapted to be mounted on a main board 90 of an electronic device (see FIG. 6), and a core mounting side 30 opposite to the contact mounting side 32. The substrate 3 is formed with a plurality of mounting holes 31 that extend from the core mounting side 30 and through the contact mounting side 32.

The iron core 5 is mounted on the core mounting side 30 of the substrate 3. In this embodiment, the iron core 5 has an elliptical cross section, and opposite end surfaces 50, 50′ that are transverse to the substrate 3 and that are formed with a pair of strand holes 51, 53 therethrough. The mounting holes 31 are formed in the substrate 3 adjacent to the end surfaces 50, 50′ of the iron core 5.

Each of the coil strands 7 passes through a respective one of the strand holes 51, 53, and is wound around the iron core 5. The coil strands 7 have opposite first and second end portions that extend to the contact mounting side 32 of the substrate 3 via the mounting holes 31, respectively. In this embodiment, the coil strands 7 include an input strand 71, a grounding strand 72, and first and second output strands 73, 74. As shown in FIG. 4, the first end portions of the input strand 71 and the first output strand 73 pass respectively through the strand holes 51, 53, are disposed adjacent to the end surface 50′ of the iron core 5, and are twisted to each other to form a first twisted pair 75. The second end portions of the input strand 71 and the first output strand 73 are disposed adjacent to the end surface 50 of the iron core 5. The first end portions of the grounding strand 72 and the second output strand 74 pass respectively through the strand holes 51, 53, are disposed adjacent to the end surface 50 of the iron core 5, and are twisted to each other to form a second twisted pair 76. The second end portions of the grounding strand 72 and the second output strand 74 are disposed adjacent to the end surface 50′ of the iron core 5.

The solder contacts 33, which are formed by solder reflow processing, are formed on the contact mounting side 32 of the substrate 3 to retain the first and second end portions of the coil strands 7 on the substrate 3 at the mounting holes 31, respectively. The solder contacts 33 are adapted to connect electrically with the main board 90 of the electronic device. The electronic device can be used for splitting cable television signals from a cable or can be assembled in a cellular telephone for signal transmission and reception processing. In this embodiment, the main board 90 is formed with a plurality of positioning holes 93 to be aligned with the mounting holes 31, respectively. The positioning holes 93 are slightly larger than the mounting holes 31 and permit extension of the solder contacts 33 thereinto, respectively.

It is noted that the substrate 3 of this invention can be produced by cutting a printed circuit board into a predetermined size, and forming the mounting holes 31 in an automated process, thereby resulting in a relatively low production cost. Furthermore, the substrate 3 can be a multi-layer circuit board for enhancing or varying impedance characteristics of the impedance device of this invention.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

We claim:

1. A surface-mountable impedance device comprising:
a substrate, formed as a non-ceramic circuit board, having a contact mounting side adapted to be mounted on a main board of an electronic device, and a core mounting side opposite to said contact mounting side, said substrate being formed with a plurality of mounting holes that extend from between said contact mounting side and through said core mounting side;
an iron core mounted on said core mounting side of said substrate, said iron core having opposite end surfaces that are transverse to said substrate and that are formed with a pair of strand holes therethrough;
a plurality of coil strands, each of which passes through a respective one of said strand holes and is wound around said iron core, said coil strands having opposite first and second end portions that extend to said contact mounting side of said substrate via said mounting holes, respectively; and
a plurality of conductive solder contacts formed on said contact mounting side of said substrate to retain said first and second end portions of said coil strands on said substrate at said mounting holes, respectively, said solder contacts being adapted to connect electrically with the main board.

2. The surface-mountable impedance device of claim 1, wherein said mounting holes are formed in said substrate adjacent to said end surfaces of said iron core.

3. The surface-mountable impedance device of claim 1, wherein said coil strands include an input strand, a grounding strand, and first and second output strands,
said first end portions of said input strand and said first output strand passing respectively through said strand holes, being disposed adjacent to one of said end surfaces of said iron core, and being twisted to each other to form a first twisted pair,
said first end portions of said grounding strand and said second output strand passing respectively through said strand holes, being disposed adjacent to the other one of said end surfaces of said iron core, and being twisted to each other to form a second twisted pair.

4. The surface-mountable impedance device of claim 3, wherein said second end portions of said input strand and said first output strand are disposed adjacent to the other one of said end surfaces of said iron core, and said second end portions of said grounding strand and said second output strand are disposed adjacent to said one of said end surfaces of said iron core.

5. The surface-mountable impedance device of claim 1, wherein said solder contacts are formed by solder reflow processing.
